(19) United States
(12) Patent Application Publication
(10) Pub. No.: US 2024/0030350 A1
(43) Pub. Date: Jan. 25, 2024

(54) DRIVING SUBSTRATE, PREPARATION METHOD THEREOF, AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Chuanbao LUO, Shenzhen (CN)

(21) Appl. No.: 17/621,166

(22) PCT Filed: Dec. 16, 2021
(86) PCT No.: PCT/CN2021/138788

§ 371 Date: Dec. 20, 2021

(30) Foreign Application Priority Data
Dec. 8, 2021 (CN) 202111491826.9

(51) Int. Cl. H01L 29/786; H01L 27/12

(52) U.S. Cl. CPC H01L 29/78606; H01L 27/1225; H01L 29/7869; H01L 27/127

(57) ABSTRACT

A driving substrate, a preparation method thereof, and a display panel are disclosed. The driving substrate includes a base, an oxide semiconductor layer, an etch stop layer (ESL) and a water-oxygen barrier layer which are sequentially arranged. The oxide semiconductor layer includes a channel. The ESL covers the channel. An orthographic projection of the water-oxygen barrier layer on a plane where the base is located at least partially overlaps with that of the channel on the plane where the base is located.

### FIELD OF INVENTION

The present application relates to the technical field of display, and particularly to a driving substrate, a preparation method thereof, and a display panel.

### BACKGROUND OF INVENTION

Mini light-emitting diode (Mini LED) and micro light-emitting diode (Micro LED) display technologies have entered an accelerated development stage in the past two years, and are gradually applied to the field of small and medium-sized displays with high added value. Compared with organic light-emitting diode (OLED) display screens, Mini LED/Micro LED display screens are more advantageous in cost, contrast, brightness, and appearance.

### SUMMARY OF INVENTION

### Technical Problem

In the Mini LED/Micro LED display technology, a back-plane technology is the key technology. Currently, types of oxide Thin Film Transistors (TFTs) in existing back-planes are mainly divided into a Coplanar type, an Etch Stop Layer (ESL) type, a Back Channel Etch (BCE) type, etc. However, in an ESL-type TFT device of a conventional art, a silicon nitride with a good water-oxygen barrier effect is generally used as a material of an ESL, so as to improve the water-oxygen barrier performance of the device. However, since a hydrogen-containing gas is present in a silicon nitride film-forming process, there is a small amount of hydrogen in the ESL. When hydrogen is diffused into a channel below the ESL, a negative drift is easily generated in the TFT device, thereby reducing the driving performance of the TFT device.

### Technical Solution

Embodiments of the present application provide a driving substrate, a preparation method thereof, and a display panel, to reduce the probability that a negative drift is generated in a Thin Film Transistor (TFT) device at the same time of improving the water-oxygen barrier performance of the TFT device.

An embodiment of the present application provides a driving substrate, which includes:
a base;
an oxide semiconductor layer, arranged on the base and including a channel;
an ESL, arranged on the oxide semiconductor layer and covering the channel; and
a water-oxygen barrier layer, arranged on the ESL. An orthographic projection of the water-oxygen barrier layer on a plane where the base is located at least partially overlaps with an orthographic projection of the channel on the plane where the base is located.

Optionally, in some embodiments of the present application, the orthographic projection of the channel on the plane where the base is located is located inside the orthographic projection of the water-oxygen barrier layer on the plane where the base is located.

Optionally, in some embodiments of the present application, the oxide semiconductor layer further includes a source portion and drain portion which are located on opposite two sides of the channel. The water-oxygen barrier layer covers the ESL and exposes the source portion and the drain portion.

The driving substrate further includes a source and a drain, both of which are arranged on a side of the water-oxygen barrier layer away from the ESL. The source is connected to the source portion. The drain is connected to the drain portion.

Optionally, in some embodiments of the present application, a material of the source portion and a material of the drain portion are both conductors.

Optionally, in some embodiments of the present application, the driving substrate further includes a gate located between the base and the oxide semiconductor layer. A width of the gate is less than or equal to a width of the water-oxygen barrier layer in a direction from the source to the drain.

Optionally, in some embodiments of the present application, the width of the gate is more than or equal to a width of the ESL in the direction from the source to the drain.

Optionally, in some embodiments of the present application, the width of the gate is equal to a length of the channel in the direction from the source to the drain.

Optionally, in some embodiments of the present application, a material of the ESL includes a silicon oxide. A material of the water-oxygen barrier layer includes a metal oxide.

Optionally, in some embodiments of the present application, the metal oxide includes one or more of alumina, titania, and zirconia.

An embodiment of the present application provides a display panel, which includes a driving substrate. The driving substrate includes:
a base;
an oxide semiconductor layer, arranged on the base and including a channel;
an ESL, arranged on the oxide semiconductor layer and covering the channel; and
a water-oxygen barrier layer, arranged on the ESL. An orthographic projection of the water-oxygen barrier layer on a plane where the base is located at least partially overlaps with an orthographic projection of the channel on the plane where the base is located.

Optionally, in some embodiments of the present application, the orthographic projection of the channel on the plane where the base is located is located inside the orthographic projection of the water-oxygen barrier layer on the plane where the base is located.

Optionally, in some embodiments of the present application, the oxide semiconductor layer further includes a source portion and drain portion which are located on opposite two sides of the channel. The water-oxygen barrier layer covers the ESL and exposes the source portion and the drain portion.

The driving substrate further includes a source and a drain, both of which are arranged on a side of the water-oxygen barrier layer away from the ESL. The source is connected to the source portion. The drain is connected to the drain portion.

Optionally, in some embodiments of the present application, a material of the source portion and a material of the drain portion are both conductors.

Optionally, in some embodiments of the present application, the driving substrate further includes a gate located between the base and the oxide semiconductor layer. A width of the gate is less than or equal to a width of the water-oxygen barrier layer in a direction from the source to the drain.

Optionally, in some embodiments of the present application, the width of the gate is equal to a length of the channel in the direction from the source to the drain.

Optionally, in some embodiments of the present application, a material of the ESL includes a silicon oxide. A material of the water-oxygen barrier layer includes a metal oxide.

Optionally, in some embodiments of the present application, the metal oxide includes one or more of alumina, titania, and zirconia.

An embodiment of the present application also provides a preparation method for a driving substrate, which includes the following steps:
providing a base;
forming an oxide semiconductor base layer on the base, the oxide semiconductor base layer including a channel;
forming an ESL on the oxide semiconductor base layer, the ESL covering the channel;
forming a water-oxygen barrier base layer on the ESL; and
patterning the water-oxygen barrier base layer and the oxide semiconductor base layer to form a water-oxygen barrier layer and an oxide semiconductor layer respectively. An orthographic projection of the water-oxygen barrier layer on a plane where the base is located at least partially overlaps with an orthographic projection of the channel on the plane where the base is located.

Optionally, in some embodiments of the present application, the ESL exposes portions of the oxide semiconductor base layer on opposite two sides of the channel after the step of forming an ESL on the oxide-semiconductor base layer.

The step of forming a water-oxygen barrier base layer on the ESL includes:
forming a metal layer on the ESL and the exposed portions of the oxide semiconductor base layer; and
performing thermal annealing treatment on the metal layer to form the water-oxygen barrier base layer. A portion of the oxide semiconductor base layer contacting with the metal layer is subjected to conductive treatment.

Optionally, in some embodiments of the present application, the step of patterning the water-oxygen barrier base layer and the oxide semiconductor base layer includes:

patterning, under the same photo-mask, the water-oxygen barrier base layer and the oxide semiconductor base layer subjected to conductive treatment to form the water-oxygen barrier layer and the oxide semiconductor layer respectively. The oxide semiconductor layer includes a source portion and drain portion which are located on opposite two sides of the channel. The water-oxygen barrier layer exposes the source portion and the drain portion respectively.

Beneficial Effects

Compared with a driving substrate in the conventional art, the driving substrate provided in the present application has the advantages that the probability that external water and oxygen invade the channel may be reduced by use of the barrier action of the water-oxygen barrier layer on the external water and oxygen. Furthermore, the requirement on the water-oxygen barrier performance of the ESL may be reduced, and the introduction of hydrogen due to the use of a material with high water-oxygen barrier performance such as a silicon nitride is avoided. Therefore, the probability that a negative drift is generated in a TFT device is reduced at the same time of improving the water-oxygen barrier performance of the TFT device, which further contributes to improving the driving performance of the driving substrate to improve the reliability of the driving substrate.

### BRIEF DESCRIPTION OF DRAWINGS

In order to explain the technical solutions in the embodiments of the present application more clearly, the following description is made to briefly introduce the accompanying drawings which are used in the description of the embodiments and are merely some embodiments of the present application; for a person skilled in the art, without involving any inventive effort, further figures can be obtained according to these figures.

FIG. 1 is a structural schematic diagram of a driving substrate according to the present application.

FIG. 2 is a schematic diagram of a plane structure of a Thin Film Transistor (TFT) of a driving substrate according to the present application.

FIG. 3 is a structural schematic diagram of a driving substrate according to the conventional art.

FIG. 4 is a schematic flowchart of a preparation method for a driving substrate according to the present application.

FIGS. 5A to 5H are schematic diagrams of structures sequentially obtained in each stage in the preparation method for a driving substrate shown in FIG. 4.

### DETAILED DESCRIPTION OF PREFERRED EMBODIMENTS

Reference will now be made in detail to the embodiments of the present disclosure, examples of which are illustrated in the accompanying drawings. It is to be understood that the present disclosure is intended to be illustrative only and is not intended to be exhaustive. Based on the embodiments in the present application, all the other embodiments obtained by a person skilled in the art without involving any inventive effort fall within the scope of protection of the present application. Furthermore, it should be understood that the particular embodiments described herein are illustrative and explanatory only and are not restrictive of the application. In the present application, the use of directional words such as “upper” and “lower” in the absence of a statement to the contrary generally means upper and lower when the device is in actual use or operation, particularly in the direction of the drawing in the drawings. The terms “inner” and “outer” refer to the contour of the device.

The embodiments of the present application provide a driving substrate, a preparation method thereof, and a display panel. Each is described in detail below. It should be noted that the order of description of the following examples is not intended to limit the preferred order of the examples.

The present application provides a driving substrate, which includes a base, an oxide semiconductor layer, an Etch Stop Layer (ESL), and a water-oxygen barrier layer. The oxide semiconductor layer is arranged on the base. The oxide semiconductor layer includes a channel. The ESL is arranged on the oxide semiconductor layer. The ESL covers the channel. The water-oxygen barrier layer is arranged on the ESL. An orthographic projection of the water-oxygen barrier layer on a plane where the base is located at least partially overlaps with that of the channel on the plane where the base is located.

Accordingly, the driving substrate provided in the present application has the water-oxygen barrier layer arranged on a side of the ESL away from the channel, and the orthographic projection of the water-oxygen barrier layer on the plane where the base is located at least partially overlaps with that of the channel on the plane where the base is located. According to the present application, the probability that external water and oxygen invade the channel may be reduced by use of the barrier action of the water-oxygen barrier layer on the external water and oxygen. Furthermore, the requirement on the water-oxygen barrier performance of the ESL may be reduced, and the introduction of hydrogen due to the use of a material with high water-oxygen barrier performance such as a silicon nitride is avoided. Therefore, the probability that a negative drift is generated in a Thin Film Transistor (TFT) device is reduced at the same time of improving the water-oxygen barrier performance of the TFT device, which further contributes to improving the driving performance of the driving substrate to improve the reliability of the driving substrate.

The driving substrate provided in the present application will be described below in detail with a specific embodiment.

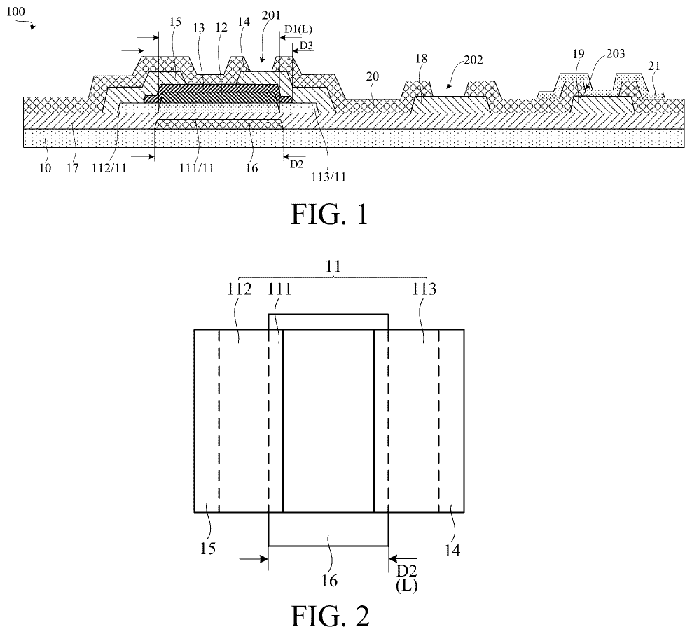

Referring to FIG. 1, the embodiment of the present application provides a driving substrate 100. The driving substrate 100 includes a base 10, an oxide semiconductor layer 11, an ESL 12, and a water-oxygen barrier layer 13. The oxide semiconductor layer 11 is arranged on the base 10. The oxide semiconductor layer 11 includes a channel 111. The ESL 12 is arranged on the oxide semiconductor layer 11. The ESL 12 covers the channel 111. The water-oxygen barrier layer 13 is arranged on the ESL 12. An orthographic projection of the water-oxygen barrier layer 13 on a plane where the base 10 is located at least partially overlaps with that of the channel 111 on the plane where the base 10 is located.

Specifically, the base 10 may be a rigid substrate, e.g., a glass substrate. Alternatively, the base 10 may be a flexible substrate, e.g., a polyimide substrate. A material of the base 10 is not specifically limited in the present application.

The ESL 12 may completely cover the channel 111, or may partially cover the channel 111. The present embodiment is described with, but not limited to, the complete covering of the channel 111 by the ESL 12 as an example only. Further, a width D1 of the ESL 12 may be greater than a length L of the channel 111, or may be equal to the length L of the channel 111. In the present embodiment, the width D1 of the ESL 12 is equal to the length L of the channel 111.

In the present embodiment, a material of the ESL 12 is a silicon oxide. The silicon oxide has high water-oxygen barrier performance, and no hydrogen-containing gas is needed by a silicon oxide film-forming process. Therefore, the ESL 12 of the present embodiment is hydrogen-free. That is, a negative drift of a device caused by the diffusion of hydrogen into the channel 111 may be avoided.

An orthographic projection of the ESL 12 on the plane where the base 10 is located is located inside that of the water-oxygen barrier layer 13 on the plane where the base 10 is located. That is, the water-oxygen barrier layer 13 completely covers the ESL 12. Therefore, the protection effect of the water-oxygen barrier layer 13 on the ESL 12 is maximized, and the requirement on the water-oxygen barrier performance of the ESL 12 may further be reduced. The orthographic projection of the ESL 12 on the plane where the base 10 is located may completely overlap with that of the water-oxygen barrier layer 13 on the plane where the base is located. Alternatively, the orthographic projection of the ESL 12 on the plane where the base 10 is located may completely fall in that of the water-oxygen barrier layer 13 on the plane where the base 10 is located. The present embodiment is described only with the latter as an example, but may not be understood as a limit to the present application. It is to be noted that, in some embodiments, the water-oxygen barrier layer 13 may also partially cover the ESL 12. Elaborations are omitted herein.

In the present embodiment, the orthographic projection of the channel 111 on the plane where the base 10 is located is located in that of the water-oxygen barrier layer 13 on the plane where the base 10 is located. That is, the water-oxygen barrier layer 13 completely covers the channel 111. With such a setting that the water-oxygen barrier layer 13 completely covers the channel 111, the water-oxygen barrier effect of the water-oxygen barrier layer 13 may be maximized. Furthermore, the water-oxygen barrier performance of the driving substrate 100 may be improved greatly by the dual water-oxygen barrier effects of the water-oxygen barrier layer 13 and the ESL 12. Therefore, the reliability of the driving substrate 100 is improved.

A material of the water-oxygen barrier layer 13 may include a metal oxide. Specifically, the metal oxide may include one or more of alumina, titania, and zirconia. The metal oxide has a high density after film-forming, and thus has higher water-oxygen barrier performance than a silicon oxide material. Therefore, the water-oxygen barrier effects of the water-oxygen barrier layer 13 and the ESL 12 may be maximized, and the water-oxygen barrier performance of the driving substrate 100 may further be improved. In the present embodiment, the material of the water-oxygen barrier layer 13 is alumina.

The oxide semiconductor layer 11 further includes a source portion 112 and a drain portion 113. The source portion 112 and the drain portion 113 are located on opposite two sides of the channel 111. The water-oxygen barrier layer 13 extends from the ESL 12 onto the source portion 112 and the drain portion 113 and partially exposes the source portion 112 and the drain portion 113. It is to be noted that, in some embodiments, the water-oxygen barrier layer 13 completely exposes the source portion 112 and the drain portion 113 when the orthographic projection of the ESL 12 on the plane where the base 10 is located completely overlaps with that of the water-oxygen barrier layer 13 on the plane where the base 10 is located. Elaborations are omitted herein.

A material of the oxide semiconductor layer 11 may include one or more of Indium Gallium Zinc Oxide (IGZO), Indium Zinc Tin Oxide (IZTO), Indium Gallium Zinc Tin Oxide (IGZTO), Indium Gallium Tin Oxide (IGTO), Indium Zinc Oxide (IZO), and Indium Tin Oxide (ITO). In the present embodiment, the material of the oxide semiconductor is IGZO. That is, a material of the channel 111 is IGZO. In addition, a material of the source portion 112 and a material of the drain portion 113 are both conductors. Specifically, an IGZO film layer may be subjected to conductive treatment by thermal annealing, plasma doping, or other manners, to form a conductive source portion 112 and drain portion 113.

In the present embodiment, the IGZO film layer is subjected to conductive treatment by thermal annealing. In the thermal annealing treatment, oxygen in the IGZO film layer is extracted to further make the IGZO film layer conductive. The conductive IGZO film layer includes the source portion 112 and the drain portion 113. An oxygen content of the source portion 112 and an oxygen content of the drain portion 113 are both less than that of the channel 111.

The driving substrate 100 further includes a source 14 and a drain 15. Both the source 14 and the drain 15 are arranged on a side of the water-oxygen barrier layer 13 away from the ESL 12. The source 14 is connected to the source portion 112. The drain 15 is connected to the drain portion 113. Since the materials of the source portion 112 and the drain portion 113 are both conductors, there is relatively low contact resistance between the source 14 and the source portion 112 and relatively low contact resistance between the drain 15 and the drain portion 113. Therefore, the switching performance of the device may be improved.

Further, the driving substrate 100 further includes a gate 16 and gate insulation layer 17 which are arranged on the base 10. The gate insulation layer 17 is located between the gate 16 and the oxide semiconductor layer 11.

A material of the gate 16 may include one or more of molybdenum, aluminum, copper, and titanium, or may include an alloy consisting of at least two of the above-mentioned metals. It is to be noted that the gate 16 may be of a single-layer structure, a double-layer structure, or a multilayer structure. The present embodiment is described with, but not limited to, the condition that the gate 16 is of a single-layer structure as an example only.

Referring to both FIGS. 1 and 2, in a direction from the source 14 to the drain 15, a width D2 of the gate 16 is less than or equal to a width D3 of the water-oxygen barrier layer 13 and more than or equal to the width D1 of the ESL 12. Such a setting may reduce the size of the TFT and further meet a design requirement of a high-resolution panel. In the present embodiment, the width D2 of the gate 16 is equal to the width D1 of the ESL 12. That is, the width D2 of the gate 16 is equal to the length L of the channel 111. The size of the TFT may further be reduced maximally.

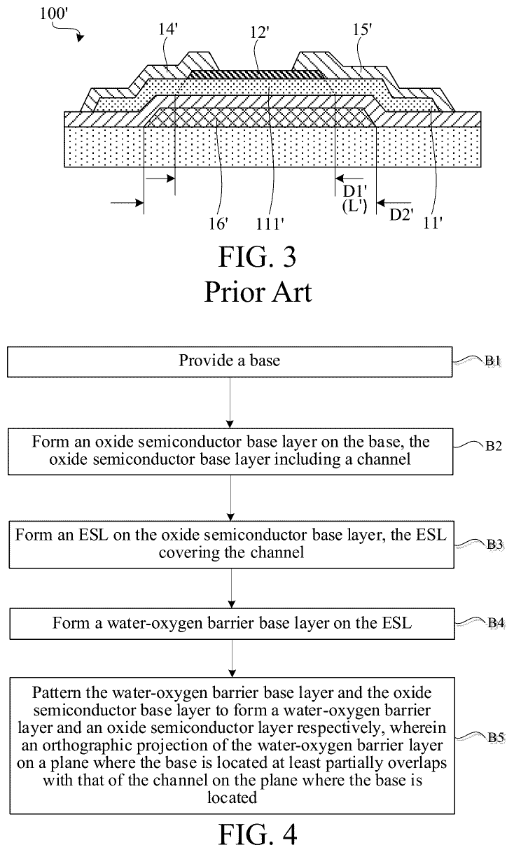

In a driving substrate 100′ of the conventional art, as shown in FIG. 3, for example, a width D1′ of an ESL 12′ is equal to a width L′ of a channel 111′. Since no conductive treatment procedure is performed for an oxide semiconductor layer 11′, a gate 16′ usually needs to have a relatively large width. Specifically, a width D2′ of the gate 16′ is usually greater than the width D1′ of the ESL 12′ in a direction from a source 14′ to a drain 15′. Therefore, electron motions in a contact region of the source 14′ and the oxide semiconductor layer 11′ and a contact region of the drain 15′ and the oxide semiconductor layer 11′ are controlled by an electric field of the gate 16′. However, a relatively large width of the gate 16′ may enlarge the TFT and further make it impossible to meet the design requirement of a high-resolution panel.

For the foregoing technical problem in the conventional art, in the present embodiment, there are conductors on two sides of the oxide semiconductor layer 11. That is, the source portion 112 and drain portion 113 on the opposite two sides of the channel 111 are both conductive. Therefore, compared with the oxide semiconductor layer 11′ subjected to no conductive treatment in the prior art, charge carriers in the source portion 112 and drain portion 113 of the present embodiment are higher in migration rate, and electron motions in a contact region of the source 14 and the source portion 112 and electron motions in a contact region of the drain 15 and the drain portion 113 no more need to be controlled by an electric field of the gate 16. Therefore, when the size of the gate 16 is designed, the width D2 of the gate 16 may be reduced in the present embodiment. In this manner, the size of the TFT is reduced, and the design requirement of a high-resolution panel may further be met.

Further, in the present embodiment, reducing the width D2 of the gate 16 may also reduce an overlapping area between the gate 16 and the source 14 and an overlapping area between the gate 16 and the drain 15 and further reduce parasitic capacitance between the drain 16 and the source 14 and parasitic capacitance between the gate 16 and the drain 15, which contributes to reducing Resistive-Capacitive (RC) Loading of the driving substrate to improve the driving performance of the driving substrate.

A material of the gate insulation layer 17 may include one or more of a silicon oxide, a silicon nitride, and a silicon oxynitride. In addition, the gate insulation layer 17 may be of a single-layer structure, a double-layer structure, or a multilayer structure. The present embodiment is described only with the condition that the gate insulation layer 17 is of a single-layer structure as an example, but may not be understood as a limit to the present application.

Referring back to FIG. 1, in the present embodiment, the driving substrate 100 further includes a bonding pad 18, a signal input pad 19, passivation layer 20, and a guard electrode 21.

Both the bonding pad 18 and the signal input pad 19 are arranged on a side of the gate insulation layer 17 away from the base 10. Both the bonding pad 18 and the signal input pad 19 are prepared by the same process as the source 14. Specifically, the bonding pad 18 is located on a side of the source 14 away from the drain 15. The bonding pad 18 is configured to connect an external Light-Emitting Diode (LED). The bonding pad 18 may be a positive pad or a negative pad. When the bonding pad 18 is a negative pad, the bonding pad 18 is configured to connect a negative electrode of the external LED. In such case, the source 14 may be used as a positive pad configured to connect a positive electrode of the external LED. The signal input pad 19 is located on a side of the bonding pad 18 away from the source 14 and in a peripheral region (not shown in the figure). The signal input pad 19 is configured to connect an external voltage signal.

It is to be noted that, in the present embodiment, the external LED may be a Mini LED or a Micro LED. The external LED may be transferred onto the driving substrate 100. All related arts are conventional arts, and will not be elaborated herein.

The passivation layer 20 is arranged on a side of the bonding pad 18 away from the base 10. The passivation layer 20 covers the base 10, the source 14, the drain 15, a portion of the water-oxygen barrier layer 13 between the source 14 and the drain 15, the bonding pad 18, and the signal input pad 19. A first opening 201, a second opening 202 and a third opening 203 are formed in the passivation layer 20. The first opening 201 exposes the source 14. The second opening 202 exposes the bonding pad 18. The third opening 203 exposes the signal input pad 19. A material of the passivation layer 20 may include one or more of a silicon oxide, a silicon nitride, and a silicon oxynitride. It is to be noted that the passivation layer 20 may be of a single-layer structure, a double-layer structure, or a multilayer structure. The present embodiment is described with, but not limited to, the condition that the passivation layer 20 is of a single-layer structure as an example only.

The guard electrode 21 is arranged on a side of the passivation layer 20 away from the base 10. The guard electrode 21 is connected to the signal input pad 19 through the third opening 203. The guard electrode 21 is configured to protect the signal input pad 19 to prevent the signal input pad 19 from being oxidized. Specifically, a material of the guard electrode 21 may include a transparent metal oxide such as ITO and/or IZO.

The present application also provides a display panel, which includes a driving substrate. The driving substrate may be the driving substrate 100 as described in the above-mentioned embodiment. A specific structure of the driving substrate 100 may refer to the descriptions in the above-mentioned embodiment, and will not be elaborated herein.

Referring to FIG. 4, the present application also provides a preparation method for a driving substrate, which includes the following steps.
In B1, a base is provided.
In B2, an oxide semiconductor base layer is formed on the base, the oxide semiconductor base layer including a channel.
In B3, an ESL is formed on the oxide semiconductor base layer, the ESL covering the channel.
In B4, a water-oxygen barrier base layer is formed on the ESL.
In B5, the water-oxygen barrier base layer and the oxide semiconductor base layer are patterned to form a water-oxygen barrier layer and an oxide semiconductor layer respectively. An orthographic projection of the water-oxygen barrier layer on a plane where the base is located at least partially overlaps with that of the channel on the plane where the base is located.

In the preparation method for a driving substrate in the present application, the water-oxygen barrier layer is formed on the ESL, so that the water-oxygen barrier performance of the driving substrate may be improved. In the present application, the oxide semiconductor base layer and the water-oxygen barrier base layer are patterned to form the oxide semiconductor layer and the water-oxygen barrier layer after the oxide semiconductor base layer and the water-oxygen barrier base layer are formed. Therefore, in the present application, patterning processes of the water-oxygen barrier layer and the oxide semiconductor layer may be implemented in the same procedure, and an additional procedure for the arrangement of the water-oxygen barrier layer may further be avoided.

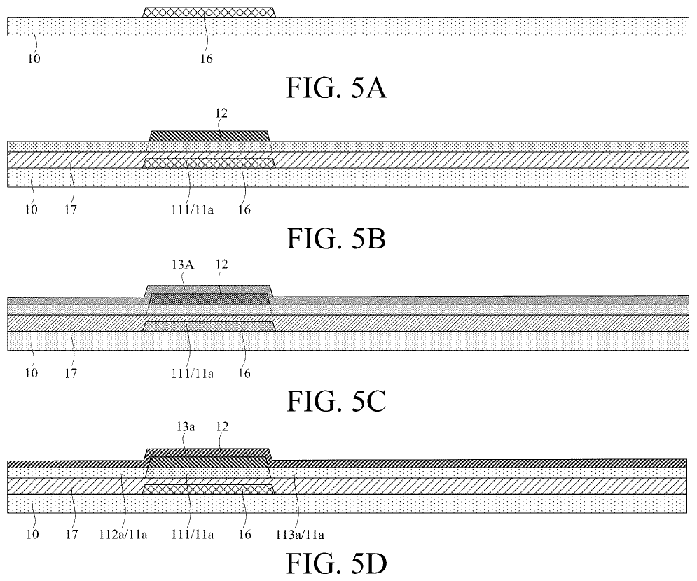

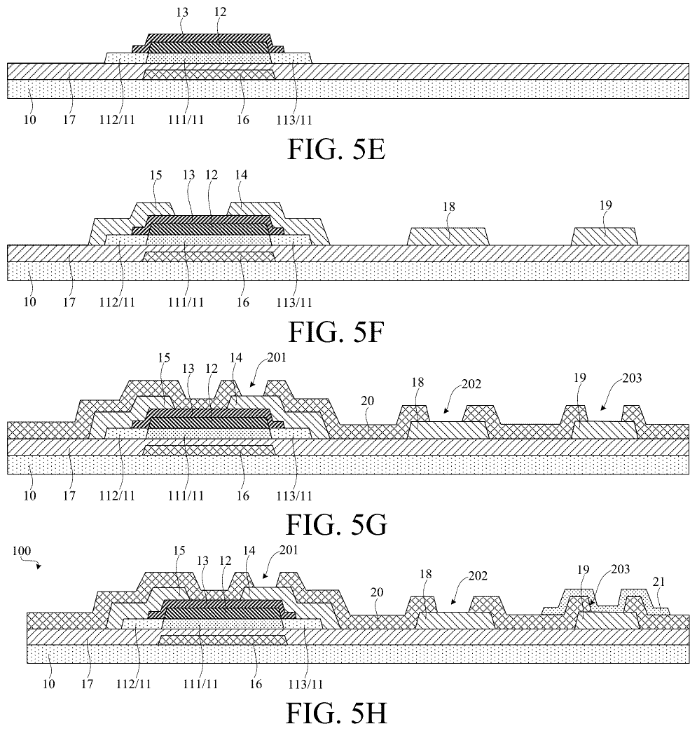

Referring to FIGS. 4 and 5A-5H, the preparation method for the driving substrate 100 in the present application will be described below in detail.

In B1, a base 10 is provided, as shown in FIG. 5A.

The base 10 may be a rigid substrate, e.g., a glass substrate. Alternatively, the base may be a flexible substrate, e.g., a polyimide substrate. A material of the base 10 is not specifically limited in the present application.

After Step B1, the following operation is further included. A gate 16 is formed on the base 10.

The gate 16 is formed at first sequentially by a physical vapor deposition process and a photo-etching process. A material of the gate 16 may include one or more of molybdenum, aluminum, copper, and titanium, or may include an alloy consisting of at least two of the above-mentioned metals. It is to be noted that the gate 16 may be of a single-layer structure, a double-layer structure, or a multilayer structure. The present embodiment is described with, but not limited to, the condition that the gate 16 is of a single-layer structure as an example only.

In B2, an oxide semiconductor base layer 11a is formed on the base 10, the oxide semiconductor base layer 11a including a channel 111, as shown in FIG. 5B.

Before the step that an oxide semiconductor layer 11a is formed, the following operation is further included.

A gate insulation layer 17 is formed on the gate 16 by a chemical vapor deposition process. A material of the gate insulation layer 17 may include one or more of a silicon oxide, a silicon nitride, and a silicon oxynitride. It is to be noted that the gate insulation layer 17 may be of a single-layer structure, a double-layer structure, or a multilayer structure. The present embodiment is described only with the condition that the gate insulation layer 17 is of a single-layer structure as an example, but may not be understood as a limit to the present application.

After the step that a gate insulation layer 17 is formed, the oxide semiconductor base layer 11a is formed at first on the gate insulation layer 17 by a physical vapor deposition process. A material of the oxide semiconductor base layer 11a may include one or more of IGZO, IZTO, IGZTO, IGTO, IZO, and ITO. Then, the oxide semiconductor base layer 11a is annealed to reduce internal defects of the oxide semiconductor base layer 11a.

In the present embodiment, the oxide semiconductor base layer 11a includes the channel 111. A length of the channel 111 is equal to a width of the gate 16.

In B3, an ESL 12 is formed on the oxide semiconductor base layer 11a, the ESL 12 covering the channel 111, as shown in FIG. 5B.

Specifically, the ESL 12 is formed sequentially by a chemical vapor deposition process and a photo-etching process. In the present embodiment, a width of the ESL 12 is equal to the length of the channel 111. The ESL 12 exposes portions of the oxide semiconductor base layer 11a on opposite two sides of the channel 111.

A material of the ESL 12 may include a silicon oxide. It is to be noted that the ESL 12 may be of a single-layer structure, a double-layer structure, or a three-layer structure. The present embodiment is described with, but not limited to, the condition that the ESL 12 is of a single-layer structure as an example only.

In B4, a water-oxygen barrier base layer 13a is formed on the ESL 12.

Step B4 specifically includes the following steps.

First, a metal layer 13A is formed on the ESL 12 and the exposed portions of the oxide semiconductor base layer 11a, as shown in FIG. 5C. Specifically, the metal layer 13A is formed by a physical vapor deposition process. A thickness of the metal layer 13A may range from 50 angstroms to 200 angstroms. A material of the metal layer 13A may include one or more of aluminum, titanium, and zirconium. In the present embodiment, the material of the metal layer 13A is aluminum.

Then, the metal layer 13A is subjected to thermal annealing treatment to form the water-oxygen barrier base layer 13a. Meanwhile, a portion of the oxide semiconductor base layer 11a contacting with the metal layer 13A is subjected to conductive treatment, as shown in FIG. 5D. A portion of the oxide semiconductor base layer 11a on one side of the channel 111 forms a source base portion 112a. A portion of the oxide semiconductor base layer 11a on the other side of the channel 111 forms a drain base portion 113a.

In the step that the metal layer 13A is subjected to thermal annealing treatment, the thermal annealing treatment includes oxidization and thermal treatment. That is, the metal layer 13A is treated in an oxygen atmosphere and a high-temperature environment. Aluminum in the metal layer 13A is oxidized to alumina in an oxidization process. Since an alumina thin film has a high density, the water-oxygen barrier base layer 13a has relatively high water-oxygen barrier performance. In addition, the metal layer 13A directly contacts with the portions of the oxide semiconductor base layer 11a on the two sides of the channel 111. Therefore, during the thermal treatment, aluminum in the metal layer 13A may be diffused into the oxide semiconductor base layer 11a at a high temperature, and oxygen in the oxide semiconductor base layer 11a is further extracted to implement the conductive treatment on the portions of the oxide semiconductor base layer 11a on the two sides of the channel 111 to form the source base portion 112a and the drain base portion 113a respectively. An oxygen content of the source base portion 112a and an oxygen content of the drain base portion 113a are both less than that of the channel 111.

In B5, the water-oxygen barrier base layer 13a and the oxide semiconductor base layer 11a are patterned to form a water-oxygen barrier layer 13 and an oxide semiconductor layer 11 respectively. An orthographic projection of the water-oxygen barrier layer 13 on a plane where the base 10 is located at least partially overlaps with that of the channel 111 on the plane where the base 10 is located, as shown in FIG. 5E.

The water-oxygen barrier base layer 13a and the oxide semiconductor base layer 11a subjected to conductive treatment are patterned under the same photo-mask, e.g., a half-tone photo-mask or a gray-scale photo-mask, to form the water-oxygen barrier layer 13 and the oxide semiconductor layer 11 respectively. The source base portion 112a forms a source portion 112. The drain base portion 113a forms a drain portion 113. The channel 111, the source portion 112 and the drain portion 113 form the oxide semiconductor layer 11. The water-oxygen barrier layer 13 partially exposes the source portion 112 and the drain portion 113 respectively.

Since the water-oxygen barrier layer 13 and the oxide semiconductor layer 11 may be formed under the same photo-mask, in the present embodiment, the water-oxygen barrier layer 13 is arranged to protect the channel 111 without increasing the number of used photo-masks. Therefore, the increase of the manufacturing cost of the process is avoided.

After Step B5, the following steps are further included.

First, a source 14 and a drain 15 are formed on the water-oxygen barrier layer 13 sequentially by a physical vapor deposition process and a photo-etching process, as shown in FIG. 5F. A material of each of the source 14 and the drain 15 may include one or more of molybdenum, aluminum, copper, and titanium, or may include an alloy consisting of at least two of the above-mentioned metals. It is to be noted that each of the source 14 and the drain 15 may be of a single-layer structure, a double-layer structure, or a multilayer structure. The present embodiment is described with, but not limited to, the condition that each of the source 14 and the drain 15 is of a single-layer structure as an example only.

In addition, a bonding pad 18 and a signal input pad 19 may be formed at the same time of forming the source 14 and the drain 15. The bonding pad 18 is located on a side of the source 14 away from the drain 15. The bonding pad 18 is configured to connect an external LED. The bonding pad 18 may be a positive pad or a negative pad. When the bonding pad 18 is a negative pad, the bonding pad 18 is configured to connect a negative electrode of the external LED. In such case, the source 14 may be used as a positive pad configured to connect a positive electrode of the external LED. The signal input pad 19 is located on a side of the bonding pad 18 away from the source 14 and in a peripheral region (not shown in the figure). The signal input pad 19 is configured to connect an external voltage signal.

It is to be noted that, in the present embodiment, the external LED may be a Mini LED or a Micro LED. The external LED may be transferred onto the driving substrate 100. All related arts are conventional arts, and will not be elaborated herein.

Then, a passivation layer 20 is formed on the source 14, the drain 15, a portion of the water-oxygen barrier layer 13 between the source 14 and the drain 15, the bonding pad 18 and the signal input pad 19 by a chemical vapor deposition process. Next, a first opening 201, a second opening 202 and a third opening 203 are formed in the passivation layer 20 by a photo-etching process, as shown in FIG. 5G. The first opening 201 exposes the source 14. The second opening 202 exposes the bonding pad 18. The third opening 203 exposes the signal input pad 19.

Specifically, a material of the passivation layer 20 may include one or more of a silicon oxide, a silicon nitride, and a silicon oxynitride. It is to be noted that the passivation layer 20 may be of a single-layer structure, a double-layer structure, or a multilayer structure. The present embodiment is described with, but not limited to, the condition that the passivation layer 20 is of a single-layer structure as an example only.

Finally, a guard electrode 21 is formed on the passivation layer 20. The guard electrode 21 is connected to the signal input pad 19 through the third opening 203, as shown in FIG. 5H. The guard electrode 21 is configured to protect the signal input pad 19 to prevent the signal input pad 19 from being oxidized. A material of the guard electrode 21 may include a transparent metal oxide such as ITO or IZO.

Hereto, the preparation method for the driving substrate 100 in the present application is completed.

A driving substrate, a preparation method thereof and a display panel provided by the embodiments of the present application are described in detail above, and the principles and embodiments of the present application are described herein by using specific examples; the description of the embodiments above is merely used to help understand the method of the present application and the core idea thereof. At the same time, for those skilled in the art, according to the idea of the present application, there will be changes in the specific embodiments and the scope of application. In summary, the contents of the description should not be construed as limiting the present application.

What is claimed is:

1. A driving substrate, comprising:
a base;
an oxide semiconductor layer, arranged on the base and comprising a channel;
an etch stop layer (ESL), arranged on the oxide semiconductor layer and covering the channel; and
a water-oxygen barrier layer, arranged on the ESL, wherein an orthographic projection of the water-oxygen barrier layer on a plane where the base is located at least partially overlaps with an orthographic projection of the channel on the plane where the base is located.

2. The driving substrate according to claim 1, wherein the orthographic projection of the channel on the plane where the base is located is located inside the orthographic projection of the water-oxygen barrier layer on the plane where the base is located.

3. The driving substrate according to claim 2, wherein the oxide semiconductor layer further comprises a source portion and drain portion which are located on opposite two sides of the channel, and the water-oxygen barrier layer covers the ESL and exposes the source portion and the drain portion; and
the driving substrate further comprises a source and a drain, both of the source and the drain are arranged on a side of the water-oxygen barrier layer away from the ESL, the source is connected to the source portion, and the drain is connected to the drain portion.

4. The driving substrate according to claim 3, wherein a material of the source portion and a material of the drain portion are both conductors.

5. The driving substrate according to claim 4, further comprising a gate located between the base and the oxide semiconductor layer, wherein a width of the gate is less than or equal to that of the water-oxygen barrier layer in a direction from the source to the drain.

6. The driving substrate according to claim 5, wherein the width of the gate is more than or equal to a width of the ESL in the direction from the source to the drain.

7. The driving substrate according to claim 5, wherein the width of the gate is equal to a length of the channel in the direction from the source to the drain.

8. The driving substrate according to claim 1, wherein a material of the ESL comprises a silicon oxide, and a material of the water-oxygen barrier layer comprises a metal oxide.

9. The driving substrate according to claim 8, wherein the metal oxide comprises one or more of alumina, titania, or zirconia.

10. A display panel, comprising the driving substrate according to claim 1.

11. The display panel according to claim 10, wherein the orthographic projection of the channel on the plane where the base is located is located inside the orthographic projection of the water-oxygen barrier layer on the plane where the base is located.

12. The display panel according to claim 11, wherein the oxide semiconductor layer further comprises a source portion and drain portion which are located on opposite two sides of the channel, and the water-oxygen barrier layer covers the ESL and exposes the source portion and the drain portion; and
the driving substrate further comprises a source and a drain, both of the source and the drain are arranged on a side of the water-oxygen barrier layer away from the ESL, the source is connected to the source portion, and the drain is connected to the drain portion.

13. The display panel according to claim 12, wherein a material of the source portion and a material of the drain portion are both conductors.

14. The display panel according to claim 13, wherein the driving substrate further comprises a gate located between the base and the oxide semiconductor layer, and a width of the gate is less than or equal to a width of the water-oxygen barrier layer in a direction from the source to the drain.

15. The display panel according to claim 14, wherein the width of the gate is equal to a length of the channel in the direction from the source to the drain.

16. The display panel according to claim 10, wherein a material of the ESL comprises a silicon oxide, and a material of the water-oxygen barrier layer comprises a metal oxide.

17. The display panel according to claim 16, wherein the metal oxide comprises one or more of alumina, titania, or zirconia.

18. A preparation method for a driving substrate, comprising following steps:
providing a base;
forming an oxide semiconductor base layer on the base, the oxide semiconductor base layer comprising a channel;
forming an etch stop layer (ESL) on the oxide semiconductor base layer, the ESL covering the channel;
forming a water-oxygen barrier base layer on the ESL; and
patterning the water-oxygen barrier base layer and the oxide semiconductor base layer to form a water-oxygen barrier layer and an oxide semiconductor layer respectively, wherein an orthographic projection of the water-oxygen barrier layer on a plane where the base is located at least partially overlaps with an orthographic projection of the channel on the plane where the base is located.

19. The preparation method for a driving substrate according to claim 18, wherein the ESL exposes portions of the oxide semiconductor base layer on opposite two sides of the channel after the step of forming an ESL on the oxide-semiconductor base layer; and
the step of forming a water-oxygen barrier base layer on the ESL comprises:
forming a metal layer on the ESL and the exposed portions of the oxide semiconductor base layer, and
performing thermal annealing treatment on the metal layer to form the water-oxygen barrier base layer. A portion of the oxide semiconductor base layer contacting with the metal layer is subjected to conductive treatment.

20. The preparation method for a driving substrate according to claim 19, wherein the step of patterning the water-oxygen barrier base layer and the oxide semiconductor base layer comprises:
patterning, under the same photo-mask, the water-oxygen barrier base layer and the oxide semiconductor base layer subjected to conductive treatment to form the water-oxygen barrier layer and the oxide semiconductor layer respectively, wherein the oxide semiconductor layer comprises a source portion and drain portion which are located on opposite two sides of the channel, and the water-oxygen barrier layer exposes the source portion and the drain portion respectively.
